(19) United States
(12) Patent Application Publication
(10) Pub. No.: US 2002/0001958 A1
(43) Pub. Date: Jan. 3, 2002

(54) Method for manufacturing semiconductor device

(75) Inventor: Jae Hee Ha, Chungcheongbuk-do (KR)

Correspondence Address: Pillsbury Winthrop LLP, Intellectual Property Group, Ninth Floor, East Tower, 1100 New York Avenue, N.W., Washington, DC, 20005-3918, US

(73) Assignee: Hynix Semiconductor Inc., Ich'on (KR)

(21) Appl. No.: 09/895,294

(22) Filed: Jul. 2, 2001

(30) Foreign Application Priority Data
Jun. 30, 2000 (KR) 2000-36714

(51) Int. Cl. H01L 21/461; H01L 21/302; H01L 21/311

(52) U.S. Cl. 438/694; 438/692

(57) ABSTRACT

A method for manufacturing a semiconductor device is provided in which a polish stop point can be accurately measured for multiple layers formed of the same material. The method involves: depositing a first interlevel dielectric (ILD) film over a semiconductor substrate having steps; forming a planarization layer over the first ILD film; forming an insulation layer containing a metal over the planarization layer; forming a second ILD film over the insulation layer containing the metal; polishing the second ILD film, the insulation layer with the metal, and a portion of the planarization layer by chemical mechanical polishing (CMP), to planarize the semiconductor substrate, wherein a polish stop point is determined by measuring a variation of conductivity of byproducts from the CMP.

### BACKGROUND OF THE INVENTION

1. Field of the Invention

The present invention relates to a method for manufacturing a semiconductor device and, more particularly, to a method for manufacturing a semiconductor device in which a polish stop point can be accurately detected during polishing of multiple layers formed of the same material.

2. Description of the Related Art

In recent years, the advance of semiconductor device fabrication technologies has rapidly increased the integration density and operation speed of chips. In particular, extensive research has been focused on multilevel metal interconnect technologies for a variety of interconnect designs, and for a wide range of interconnect resistance and capacitance. A semiconductor substrate having a multilevel metal interconnect structure for a higher integration density will typically have an increased step height. A planarization process is necessary in the manufacture of such semiconductor devices to reduce this step height and improve subsequent processing. To achieve the desired degree of planarization, a planarization layer may be deposited and/or the semiconductor substrate having a step is planarized by chemical mechanical polishing (CMP). Deposition of a planarization layer alone, however, although covering the underlying steps, does not tend to provide a sufficiently planar surface. Accordingly, conventional methods tend to use both a planarization layer and a CMP process in manufacturing a semiconductor device.

FIGS. 1A and 1B are sectional views illustrating a conventional planarization method in which a planarization layer is formed and a CMP process is also performed. Referring to FIG. 1A, a conductive pattern 12 is formed on a semiconductor substrate 11. The conductive pattern 12 may be a gate electrode or a metal interconnect. A step occurs in the surface of the semiconductor substrate 11 at the edge of the conductive pattern 12. A first interlevel dielectric (ILD) film 13 is deposited over the semiconductor substrate 11 with the conductive pattern 12, and a flowable oxide layer 14, for example, a borophosphosilicate glass (BPSG) layer, is deposited to have a predetermined thickness over the first ILD film 13. The semiconductor substrate 11 is then typically subjected to a predetermined heating process to flow (or reflow) the BPSG layer 14. A second ILD film 15, for example, a plasma-enhanced tetraethylothosilicate glass (TEOS) layer, is deposited to have a predetermined thickness over the flowed oxide layer 14. Then, the second ILD film 15 and the oxide layer 14 are polished by CMP by a predetermined thickness. In this process, the polish stop point is typically determined using one or more test substrates. In particular, a test substrate having the structure described above is intentionally broken to measure the thickness of the oxide layer that has been removed by the CMP with during a predetermined time interval. These results are then used to determine an appropriate polish stop point for use on the actual production semiconductor devices.

Following are problems occurring in the conventional CMP process to multiple insulation layers formed of the same material. As previously mentioned, the polish stop point for CMP is typically determined based on the experimental data derived from test substrates. Thus, a large number of test substrates are needed to obtain data for a variety of manufacturing conditions, thereby increasing the manufacturing cost. In addition, it is impossible to monitor the CMP process in real time for a particular batch of semiconductor substrates. Because the process status of the substrate is estimated from the data obtained from the test substrates, the resulting accuracy and uniformity are poor. Accordingly, the resultant semiconductor substrates may not exhibit the desired level of uniformity.

### SUMMARY OF THE INVENTION

To solve the above problems, it is an object of the present invention to provide a method for manufacturing a semiconductor substrate, in which a polish stop point can be accurately measured for multiple layers formed of the same material.

The object of the present invention is achieved by a method for manufacturing a semiconductor device, the method comprising: depositing a first interlevel dielectric (ILD) film over a semiconductor substrate having steps; forming a planarization layer over the first ILD film; forming an insulation layer containing a metal over the planarization layer; forming a second ILD film over the insulation layer containing the metal; polishing the second ILD film, the insulation layer with the metal, and a portion of the planarization layer by chemical mechanical polishing (CMP), to planarize the semiconductor substrate, wherein a polish stop point is determined by measuring variations in the conductivity of byproducts from the CMP process in real time.

### BRIEF DESCRIPTION OF THE DRAWINGS

The above object and advantages of the present invention will become more apparent by describing in detail a preferred embodiment thereof with reference to the attached drawings in which:

FIGS. 1A and 1B are sectional views illustrating a conventional planarization method in which a planarization layer is deposited and a chemical mechanical polishing (CMP) process is applied; and

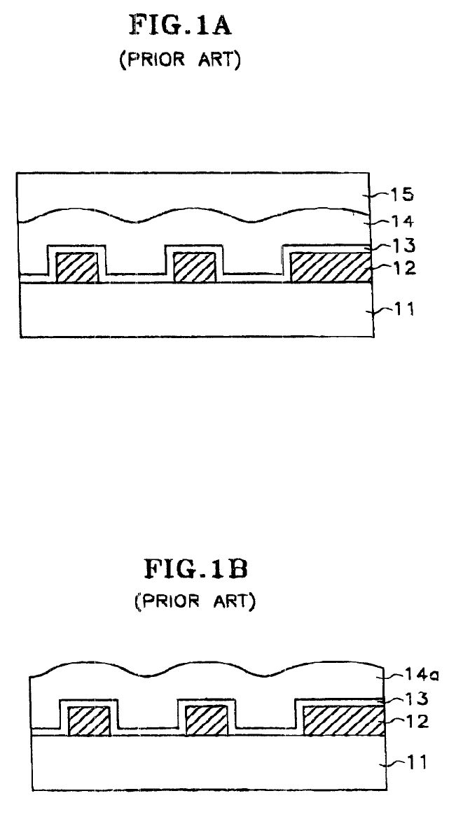

FIGS. 2A and 2B are sectional views illustrating a method for manufacturing a semiconductor device according to a preferred embodiment of the present invention.

### DETAILED DESCRIPTION OF THE INVENTION

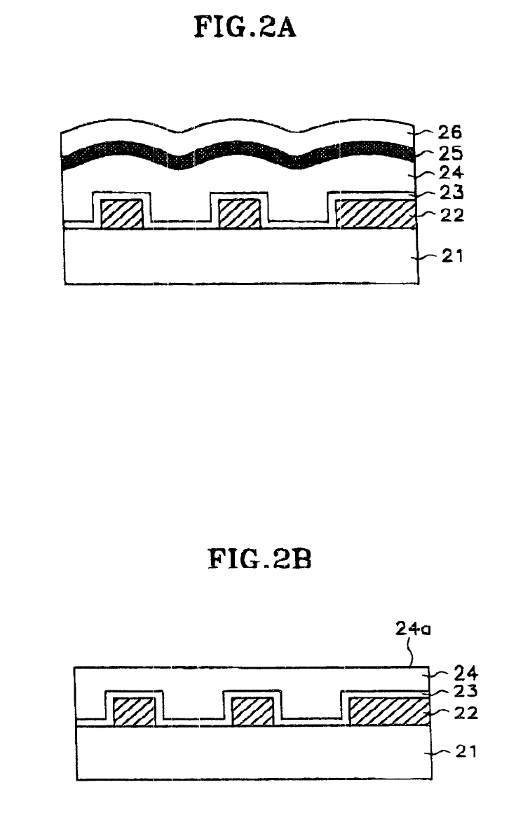

The present invention will now be described more fully with reference to FIGS. 2A and 2B, in which preferred embodiments of the invention are shown. Referring to FIG. 2A, conductive patterns 22, for example, gate electrodes or metal interconnects, are formed over a semiconductor substrate 21. The semiconductor substrate 21 may be a simple silicon substrate, or a silicon substrate with a predetermined circuit pattern. The conductive patterns 22 cause steps on the surface of the semiconductor substrate 21. Subsequently, a first interlevel dielectric (ILD) film 23 is deposited over the semiconductor substrate 21 with the conductive patterns 22. A flowable oxide layer 24, preferably a borophosphosilicate glass (BPSG) layer, is deposited to a predetermined thickness over the first ILD film 23. The semiconductor substrate 21 is then subjected to a heating process at a predetermined temperature, for example, at a temperature of 800-850° C., to flow (or reflow) the oxide layer 24. A metal oxide layer 25 which serves to determine a polish stop point is deposited over the flowed oxide layer 24. The metal oxide layer 25 may be formed from Al₂O₃, Ta₂O₅, MnO₂ or WO₃. In the preferred embodiment, the metal oxide layer 25 is formed of an Al₂O₃ layer. A second ILD film 26, for example, a plasma-enhanced tetraethylothosilicate glass (PE-TEOS) layer, is then deposited over the metal oxide layer 25.

Referring to FIG. 2B, the second ILD film 26, the metal oxide layer 25 and the flowed oxide layer 24 are polished using a chemical mechanical polishing (CMP) process. The CMP process is stopped when the metal oxide layer 25 is completely removed. Physical properties of the metal oxide layer 25 differ from those of the adjacent ILD films, and thus the metal oxide layer 25 can be used in determining the polish stop point.

In particular, as the second ILD film 26 which contains SiO₂ is polished with a slurry containing water and alkali chemicals, Si(OH) is produced as a byproduct by the reaction between the second ILD film 26 and the slurry, which can be expressed as reaction [1].

H₂O+SiO₂→2[Si—OH] [1]

Then, as the metal oxide layer 25 begins to be polished after the second ILD film 26 is removed, the effluent begins to include a metal hydroxide that is produced as a byproduct by the reaction between the metal oxide material and the slurry. For example if the metal oxide layer 25 comprises Al₂O₃, the result can be expressed as reaction [2].

H₂O+Al₂O₃→Al(OH)ₓ [2]

The metal hydroxide, for example Al(OH)x, will continue to be produced until the metal oxide layer 25 has been completely removed. According to the present invention, therefore, the CMP process is continued until the effluent is essentially free of metal hydroxide. The composition of the material(s) being removed by the CMP process can be identified by measuring the conductivity, i.e., the current level at a given potential, of the byproducts being discharged from the CMP process. For example, initially when only the second ILD film 26 is being removed, the byproducts present in the effluent produce a relatively low conductivity value. As more of the metal oxide layer 25 is exposed and subjected to the CMP process, the conductivity of the effluent increases with the increasing level of metal hydroxide. Since the surface of the flowed oxide layer 24, which has undergone a thermal process for planarization, remains partially non-planar, a portion of the oxide layer 24 is polished as the lower portions of the metal oxide layer 25 are removed. While portions of both the oxide layer 24 and the metal layer 25 are being removed simultaneously, the conductivity of the effluent remains relatively high due to the metal byproducts in solution. When the metal oxide layer 25 has been completely removed and no metal byproducts remain to provide a relatively high conductivity, the CMP process is terminated. In FIG. 2B, reference numeral 24a denotes the BPSG layer planarized by the polishing.

As previously described, when the semiconductor substrate with multiple insulation layers formed of the same material is polished using a CMP process, a metal oxide layer having different properties as those of the insulation layers is interposed between the insulation layers to serve as a polish stop point. Although the metal oxide layer is used in determining the desired a polish stop point in the present embodiment, a metal nitride layer or a metal oxynitride layer could also be used in a similar fashion.

As described above, when a semiconductor substrate having multiple insulation layers formed from substantially the same material is subjected to CMP, a metal oxide layer serving as a polish stop point is interposed between the insulation layers. The CMP process is stopped when the metal oxide layer has been completely removed. The polishing status of the layers can be monitored by measuring variations in the conductivity of the effluent resulting from changes in the composition of the polishing byproducts. As a result, accuracy and uniformity in polishing the layers can be improved. Further, the present invention eliminates the need for large numbers of test substrates that are required for conventional CMP processing, thereby lowering the manufacturing cost.

While this invention has been particularly shown and described with reference to preferred embodiments thereof, it will be understood by those skilled in the art that various changes in form and details may be made to the described embodiments without departing from the spirit and scope of the invention as defined by the appended claims.

We claim:

1. A method for manufacturing a semiconductor device, the method comprising:
depositing a first interlevel dielectric (ILD) film over a semiconductor substrate having at least one step;
forming a planarization layer over the first ILD film;
forming an insulation layer containing a metal over the planarization layer;
forming a second ILD film over the insulation layer;
polishing the second ILD film, the insulation layer, and a portion of the planarization layer using chemical mechanical polishing (CMP), to planarize the semiconductor substrate, wherein the polishing step produces an effluent;
monitoring the effluent during the polishing step to determine a conductivity value; and
terminating the polishing step when the conductivity value reaches a predetermined level.

2. A method for manufacturing a semiconductor device according to claim 1, wherein the insulation layer comprises at least one material selected from a group consisting of metal oxides, metal nitrides and metal oxynitrides.

3. A method for manufacturing a semiconductor device according to claim 1, wherein the insulation layer comprises a material selected from the group consisting of Al₂O₃, Ta₂O₅, MnO₂ and WO₃.

4. A method for manufacturing a semiconductor device according to claim 1 wherein the step of terminating the polishing step further includes an over-polish step of predetermined duration, the over-polish step being initiated when the conductivity value reaches the predetermined level.

5. A method for manufacturing a semiconductor device, the method comprising:
depositing a first interlevel dielectric film over a semiconductor substrate having at least one step;
forming a planarization layer over the first interlevel dielectric film;
forming an insulation layer containing a metal over the planarization layer;
polishing the insulation layer and a portion of the planarization layer by chemical mechanical polishing (CMP), to planarize the semiconductor substrate, wherein the polishing step produces an effluent;
monitoring the effluent during the polishing step to determine a conductivity value; and
terminating the polishing step when the conductivity value reaches a predetermined level.

6. A method for manufacturing a semiconductor device, the method comprising:
forming a semiconductor substrate having a pattern of conductive material, the pattern producing at least one step;
forming a planarization layer over the substrate and the pattern;
forming an insulation layer over the planarization layer, the insulation layer comprising a metal oxide;
polishing the substrate using a chemical mechanical polishing process to produce a planarized semiconductor substrate, the polishing step producing a liquid effluent, the effluent comprising polishing byproducts;
monitoring the effluent during the polishing step to determine a conductivity value; and
terminating the polishing step when the conductivity value reaches a predetermined level.

7. The method for manufacturing a semiconductor device according to claim 2, wherein the metal nitrides comprise a nitride including a material selected from the group consisting of Al, Ta, Mn, W and Ti.

8. The method for manufacturing a semiconductor device according to claim 2, wherein the metal oxynitrides comprise an oxynitride including a material selected from the group consisting of Al, Ta, Mn, W and Ti.

9. The method for manufacturing a semiconductor device according to claim 5, wherein the insulation layer comprises at least one material selected from the group consisting of a metal oxide, a metal nitride and a metal oxynitride.

10. The methos for manufacturing a semiconductor device according to claim 9, wherein the metal oxide comprises a oxide including a material selected from the group consisting of Al, Ta, Mn, W and Ti.

11. The method for manufacturing a semiconductor device according to claim 9, wherein the metal nitride comprises a nitride including a material selected from the group consisting of Al, Ta, Mn, W and Ti.

12. The method for manufacturing a semiconductor device according to claim 9, wherein the metal oxynitride comprises a oxynitride including a material selected from the group consisting of Al, Ta, Mn, W and Ti.

13. The method for manufacturing a semiconductor device according to claim 6, wherein the metal oxide comprises a oxide including a material selected from the group consisting of Al, Ta, Mn, W and Ti.

14. The method for manufacturing a semiconductor device according to claim 6, wherein the insulation layer comprises at least one material selected from the group consisting of a metal nitride and a metal oxynitride.

15. The method for manufacturing a semiconductor device according to claim 14, wherein the metal nitride comprises a nitride including a material selected from the group consisting of Al, Ta, Mn, W and Ti.

16. The method for manufacturing a semiconductor device according to claim 14, wherein the metal oxynitride comprises a oxynitride including a material selected from the group consisting of Al, Ta, Mn, W and Ti.
